(19) United States
(12) Patent Application Publication
(10) Pub. No.: US 2011/0266543 A1
(43) Pub. Date: Nov. 3, 2011

(54) CIRCUIT BOARD AND DISPLAY DEVICE

(76) Inventor: Hiroyuki Moriwaki, Osaka (JP)

(21) Appl. No.: 12/673,061

(22) PCT Filed: May 19, 2008
(86) PCT No.: PCT/JP2008/059125

§ 371 Date: Feb. 11, 2010

(30) Foreign Application Priority Data
Aug. 9, 2007 (JP) 2007-208372

(51) Int. Cl. H01L 33/16; H01L 29/04

(52) U.S. Cl. 257/59; 257/60; 257/66; 257/72; 257/E29.003; 257/E33.004; 257/E33.003

(57) ABSTRACT

The present invention provides a circuit board that includes top gate TFTs and bottom gate TFTs formed on the same substrate and that can improve reliability of these TFTs. The present invention is a circuit board including a bottom gate thin film transistor and a top gate thin film transistor on a substrate,
the bottom gate thin film transistor including a gate electrode, a gate insulating film, and a semiconductor layer, stacked in this order from a side of the substrate,
the top gate thin film transistor including a semiconductor layer, a gate insulating film, and a gate electrode, stacked in this order from the side of the substrate,
wherein two or more insulating films are arranged between the substrate and the semiconductor layer of the top gate thin film transistor, and
at least a base coat film arranged between the substrate and the gate electrode of the bottom gate thin film transistor, and the gate insulating film of the bottom gate thin film transistor constitute the two or more insulating films.

### TECHNICAL FIELD

The present invention relates to a circuit board and a display device. More particularly, the present invention relates to a circuit board including high-performance thin film transistors with enhanced reliability and to a display device including such a circuit board.

### BACKGROUND ART

The market of flat panel displays is now being expanded with advance information technology. The flat panel displays such as a non-self-emitting LCD (liquid crystal display), a self-emitting PDP (plasma display panel), an inorganic EL (electroluminescent) display, and an organic EL display, are known, and such displays are being actively researched and developed.

The conventional display devices have an embodiment in which a driving circuit and the like are mounted on the outer side of a display device panel. In view of reductions in costs, an area of a frame region, and panel thickness, a display device including a full-monolithic circuit board including a driver circuit and the like within a panel region on a substrate is now being researched and developed.

A TFT (thin film transistor) arranged in the driver circuit and the like needs to be operated at a high speed and at a low voltage compared with a conventional pixel switching TFT. A signal processing circuit such as a driver circuit is operated at a low voltage of about 3 to 5 V. In order for a display device to achieve high-speed display, TFTs arranged in the driver circuit need to be operated at a high speed and at a low voltage. A power supply voltage supplied to a pixel circuit is set to be about 14 to 25V, including a threshold voltage of pixel switching TFTs, a threshold voltage of liquid crystals, a voltage for gradation display, and a voltage for driving liquid crystals. So the pixel switching TFTs tend to be deteriorated because a relatively high voltage is applied thereto. Apart of the circuit used in the periphery of the display region is preferably operated at a high voltage. In view of this, it is preferable that the configuration of the TFTs that are arranged in the driver circuit is individualized according to their use.

As a technology of using TFTs according to their use, a technology of providing high-voltage TFTs and low-voltage TFTs with configurations different from each other is disclosed (for example, see Patent Documents 1 and 2). In Patent Documents 1 and 2, a top gate TFT as a low-voltage transistor and a bottom gate TFT as a high-voltage transistor are arranged on the same substrate.

### [Patent Document 1]

Japanese Kokai Publication No. Hei-11-54761

### [Patent Document 2]

Japanese Kokai Publication No. 2007-13013

### DISCLOSURE OF INVENTION

According to the circuit boards disclosed in Patent Documents 1 and 2, a gate electrode of a bottom gate TFT is arranged directly on a substrate, and thereon, a base layer of a top gate TFT that also functions as a gate insulating film of the bottom gate TFT is arranged, and further thereon, a semiconductor layer of the bottom gate and top gate TFTs is arranged. In such a configuration, for example, substrate impurities might contaminate the semiconductor layer, or an insulating property (dielectric breakdown voltage) of the gate insulating film might be reduced. Further, the base layer of the top gate TFT also functions as the gate insulating film of the bottom gate TFT, and the gate electrode of the bottom gate TFT is arranged between the gate insulating film and the substrate. In such a configuration, if a thermal diffusion property of the base layer of the top gate TFT varies from position to position, crystallinity of polycrystalline silicon might be deteriorated in a step of crystallizing the semiconductor layer. In view of this, such circuit boards have room for improvement in their reliability.

The present invention has been made in view of the above-mentioned state of the art. The present invention has an object to provide a circuit board including a top gate TFT and a bottom gate TFT on the same substrate, the TFTs having enhanced reliability.

The present inventor made various investigations on a circuit board including bottom gate and top gate TFTs on the same substrate, and noted arrangement configurations of a film arranged on the substrate side of the respective TFTs and a gate insulating film. The inventor found that impurity contamination from a substrate, a reduction in insulating property of a gate insulating film, and the like, might be generated when the circuit board is formed to have the following configuration: agate electrode of a bottom gate TFT is arranged directly on a substrate, and thereon, a base layer of a top gate TFT that also functions as a gate insulating film of the bottom gate TFT is arranged, and further thereon, a semiconductor layer of the bottom gate and top gate TFTs is arranged. Further, the inventor also found that in the circuit board having the above-mentioned configuration, a thermal diffusion property of the base layer of the top gate TFT varies from position to position, and in such a case, crystallinity of polycrystalline silicon might be deteriorated in a step of crystallizing the semiconductor layer. The inventor found that a gate insulating film having an anti-impurity contamination property and a high insulating property can be formed and further a thermal diffusion property of a base coat film can be improved, and a result, thin film transistors with high reliability can be provided if the above-mentioned circuit board including a bottom gate thin film transistor and a first top gate thin film transistor on a substrate, the bottom gate thin film transistor including a first gate electrode, a first gate insulating film, and a first semiconductor layer, stacked in this order from a side of the substrate, the first top gate thin film transistor including a second semiconductor layer, a second gate insulating film, and a second gate electrode, stacked in this order from the side of the substrate, wherein two or more insulating films are arranged between the substrate and the second semiconductor layer, and at least a base coat film arranged between the substrate and the first gate electrode, and the first gate insulating film constitute the two or more insulating films. Thus, the above-mentioned problems have been admirably solved, leading to completion of the present invention.

That is, the present invention is a circuit board including a bottom gate thin film transistor and a first top gate thin film transistor on a substrate, the bottom gate thin film transistor including a first gate electrode, a first gate insulating film, and a first semiconductor layer, stacked in this order from a side of the substrate, the first top gate thin film transistor including a second semiconductor layer, a second gate insulating film, and a second gate electrode, stacked in this order from the side of the substrate, wherein two or more insulating films are arranged between the substrate and the second semiconductor layer, and at least a base coat film arranged between the substrate and the first gate electrode, and the first gate insulating film constitute the two or more insulating films.

The present invention is mentioned in detail below. Various embodiments mentioned below may be appropriately combined.

The circuit board of the present invention includes a bottom gate thin film transistor and a first top gate thin film transistor on a substrate. The bottom gate thin film transistor includes a first gate electrode, a first gate insulating film, and a first semiconductor layer, stacked in this order from the substrate side. The first top gate thin film transistor includes a second semiconductor layer, a second gate insulating film, and a second gate electrode, stacked in this order from the substrate side. The two different kinds of TFTs i.e., the bottom gate TFT and the top gate TFT, are arranged, and they can be used depending on their use.

According to the above-mentioned bottom gate thin film transistor, the first gate electrode is partly arranged on the substrate, and thereon, the first gate insulating film is arranged, and thereon, the first semiconductor layer is arranged. If the above-mentioned first gate electrode is constituted by a metal film and if the above-mentioned circuit board is applied to a liquid crystal display device, it is preferable, in order to decrease the number of production steps, that the first gate electrode is formed by patterning the same metal film that is to constitute a storage capacitor lower electrode, which forms a storage capacitance (a capacitance for storing a voltage applied to liquid crystals when pixels that are the minimum units for displaying an image in a liquid crystal display device are driven).

The above-mentioned circuit board includes two or more insulating films between the substrate and the second semiconductor layer of the first top gate thin film transistor. If two or more insulating films are arranged below the second semiconductor layer of the first top gate thin film transistor, the material and thickness of the films can be determined according to their use. It is preferable that the two or more insulating films are made of materials different from one another.

In the present description, the terms “upper” and “above” mean a direction away from the substrate, and the terms “lower” and “below” mean a direction closer to the substrate.

At least the base coat film arranged between the substrate and the first gate electrode of the bottom gate thin film transistor, and the first gate insulating film of the bottom gate thin film transistor constitute the above-mentioned two or more insulating films. It is preferable that the base coat film is arranged directly on the entire substrate as a layer lower than the first gate electrode. In this case, thermal diffusion through the base coat film can be uniform over the entire substrate. According to this, if the first and second semiconductor layers are polycrystalline silicon films obtained by crystallizing amorphous silicon films, heat by a laser and the like is diffused uniformly over the substrate, and as a result, the crystallinity of the polycrystalline silicon can be improved. In addition, if the base coat film is a film that can effectively prevent impurity diffusion from the substrate to the first and second semiconductor layers, a film with a high insulating property can be used as the first gate insulating film. As a result, impurity diffusion can be prevented, and simultaneously, the first gate insulating film with a high insulating property can be formed. It is more preferable that the base coat film is made of a material that can relax stress generated between the substrate and the first gate electrode or the first gate insulating film. According to this, the stress generated between the substrate and either of the two materials can be relaxed, which can suppress film separation, a change in characteristics of the TET, and the like. The above-mentioned two or more insulating films may be composed of three or more films, and for example, a base coat film composed of two films and the first gate insulating film composed of two films constitute the two or more insulating films. The base coat film, and the first and second gate insulating films may be entirely or partly formed over the substrate. The arrangement positions of the base coat film, and the first and second gate insulating films are appropriately determined. According to the first top gate thin film transistor, the second semiconductor layer is formed in a layer upper than the base coat film and the first gate insulating film, and thereon, the second gate insulating film is arranged, and thereon, the second gate electrode is arranged in a region corresponding to a gate (channel region) of the first top gate TFT. The term “base coat film” used herein means a film that is arranged on a lower side (substrate side) of the bottom gate thin film transistor and the first top gate thin film transistor.

The above-mentioned base coat film is preferably a film that can effectively prevent impurity diffusion from the substrate. In this case, the first gate insulating film may have a low anti-impurity diffusion property. So a material excellent in insulating property and interfacial state to the first semiconductor layer can be used for the first gate insulating film. As mentioned above, the film capable of preventing impurity diffusion from the substrate and the gate insulating film excellent in insulating property and interfacial state to the semiconductor layer can be arranged below the second gate electrode as the two or more insulating films.

The above-mentioned circuit board includes the two or more different kinds of TFTs, i.e., the first top gate TFT and the bottom gate TFT. The first and second semiconductor layers included in the first top gate TFT and the bottom gate TFT which are different in characteristics, respectively, are simultaneously formed. As a result, the number of production steps can be decreased compared with a case where TFTs that have the same type and different characteristics are formed in different steps. If semiconductor layers of TFTs that have the same type and different characteristics are formed in the same film-forming and patterning steps and if the gate insulating films are different in thickness between the two TFTs, a gate electrode of the TFT including the gate insulating film with a smaller thickness is patterned, and then, a gate insulating film of the other TFT including the gate insulating film with a larger thickness is additionally formed. So when the gate electrode of the TFT including a gate insulating film with a smaller thickness is patterned, the gate insulating film of the other TFT including the gate insulating film with a larger thickness is damaged by etching. Further, this etching causes a variation in thickness of the gate insulating film. According to the first and second gate insulating films in the configuration of the present invention, however, damages and/or variation in thickness which might be caused by the etching do not occur. In addition, if the second gate insulating film is formed and then ion doping for providing the first and second semiconductor layers with a channel region, a source region, a drain region, and the like, is performed, the thickness of the insulating film (the second gate insulating film) through which ions pass is the same between the first top gate TFT and the bottom gate TFT, and so ion doping is easily controlled. If the above-mentioned circuit board is included in a liquid crystal display device, it is preferable that the storage capacitor lower electrode, the first gate insulating film, and the storage capacitor upper electrode are arranged in this order from the substrate side, and as a result, the storage capacitor for the pixel is formed; the storage capacitor lower electrode is formed by patterning the same metal film that is to constitute the first gate electrode; and the storage capacitor upper electrode is formed by patterning the same film that is to constitute the first and second semiconductor layers. According to this, ESD (electrostatic discharge) breakdown that is caused when the semiconductor layer covers an angular edge of the first gate insulating film can be prevented from being generated. In this embodiment, the storage capacitor upper electrode is formed within a region where the storage capacitor lower electrode is arranged as viewed in plane, and so the storage capacitor upper electrode does not cover the angular edge of the first gate insulating film. In contrast, the storage capacitor upper electrode is formed to cover the angular edge of the storage capacitor lower electrode if the storage capacitor lower electrode, the second gate insulating film, and the storage capacitor upper electrode are arranged in this order from the substrate side and as a result, the storage capacitor for the pixel is formed; the storage capacitor lower electrode is formed by patterning the same metal film that is to constitute the first and second semiconductor layers; and the storage capacitor upper electrode is formed by patterning the same metal film that is to constitute the second gate electrode. As a result, the second gate insulating film is formed to be thin at the angular edge of the storage capacitor lower electrode. This often results in ESD breakdown due to deterioration of breakdown voltage.

However, if ESD breakdown due to deterioration of resistance to pressure is within an acceptable degree, the first gate electrode (layer formed by patterning the same film to constitute the first gate electrode), the first gate insulating film, the semiconductor layer (layer formed by patterning the same film to constitute the first and second semiconductor layers), the second gate insulating film, the second gate electrode (layer formed by patterning the same film to constitute the second gate electrode), are successively formed, and as a result, a multi-layer pixel storage capacitor including the two insulating films is formed. Thus, the area of the storage capacitor for the pixel can be decreased.

Preferable embodiments of the present invention are mentioned below.

According to the above-mentioned circuit board, the first gate insulating film and the second gate insulating film are different in thickness. As a result, thin film transistors different in resistance to pressure can be formed. According to this, the TFT that includes a gate insulating film with a small thickness and that is driven at a low voltage can be used as a high-performance TFT, and the TFT that includes a gate insulating film with a large thickness can be used as a high-voltage TFT.

It is preferable that the first gate insulating film has a thickness larger than a thickness of the second gate insulating film. If the circuit board is included in a display device including TFTs as a pixel switching element, the thickness of the gate insulating film of the TFT used as a pixel switching element is set to be large. If the bottom gate TFT is used as the TFT for pixel switching, the gates in both of the TFT used as a pixel switching element and the TFT used as a bottom-gate TFT used in a circuit can be simultaneously formed in an LDD structure-forming step by self-alignment technique. The self-alignment technique is as follows. First, the second gate insulating film is formed, and thereon, a resist is applied. Then, the resist is exposed to light from the back surface side (the side opposite to the base coat film side) of the substrate using the first gate electrode as a photomask to give a mask for self-aligned doping. Then, a low concentration doping is performed from the front side (the base coat film side of the substrate). Successively, a resist is newly applied and then the source and drain regions are formed by front exposure using a photomask. As a result, the LDD structure is formed.

It is preferable that the base coat film contains silicon nitride, and it is more preferable that the base coat film is made of silicon nitride (the base coat film is a silicon nitride film). If silicon nitride is used as a material for the base coat film, diffusion of impurity ions such as Na from the substrate to the first gate electrode, the first and second semiconductor layers, and the like, can be effectively prevented.

Since the first gate insulating film is used as a gate insulating film of the bottom gate TFT, it is preferable that the first gate insulating film is excellent in insulating property and also in interfacial state to the first semiconductor layer. Silicon oxide is mentioned, for example, as a material for the first gate insulating film having such characteristics. That is, it is preferable that the first gate insulating film contains silicon oxide, and it is more preferable that the first gate insulating film is a silicon oxide film formed using tetraethyl orthosilicate (TEOS) as raw material gas. The first gate insulating film can be excellent in insulating property because it is a film formed using silicon oxide, especially TEOS, as raw material gas. As a result, the thickness of the first gate insulating film can be decreased, which leads to improvement in performances of the bottom gate TFT. The silicon oxide film is compatible with silicon generally used in the semiconductor layer because it is made of oxidized silicon. The silicon oxide film is arranged between the first semiconductor layer and another layer arranged on the substrate side of the first semiconductor layer to function as a buffer layer and to improve crystallinity of the first semiconductor layer. The above-mentioned circuit board includes at least base coat film below the first gate insulating film, and so the first gate insulating film may have a function of preventing impurity diffusion from the substrate.

It is preferable that the circuit board further includes a double gate thin film transistor, the double gate thin film transistor is composed of the bottom gate thin film transistor and a second top gate thin film transistor formed in a region overlapping with the bottom gate thin film transistor. Thus, the circuit board may include a double gate thin film transistor having composed of the bottom gate thin film transistor and the second top gate thin film transistor, stacked one above the other. It is more preferable that the double gate thin film transistor has a multi-layer structure where the semiconductor layer is common between the bottom gate thin film transistor and the top gate thin film transistor. In such a case, the first gate electrode, the first gate insulating film, the first semiconductor layer, the second gate insulating film, and the third gate electrode are stacked in this order from the substrate side. The “double gate thin film transistor” is a thin film transistor including two gates for a pair of source and drain. If a driving voltage of the thin film transistor is decreased in order to reduce electric power consumption, the electric current amount of the thin film transistor is decreased. In order to reduce electric power consumption without decreasing the electric current amount, a channel length is tried to be shortened by fine processing or the thickness of the gate insulating film is tried to be decreased. However, in the fine processing, reliability of the thin film transistor might be deteriorated. If the double gate thin film transistor is arranged, an electric current in an amount corresponding to that of upper and lower two transistors can be carried. For example, if a double gate thin film transistor is composed of two thin film transistors, i.e., a top gate thin film transistor and a bottom gate thin film transistor, two thin film transistors are used for a pair of source and drain electrodes. As a result, reliability can be improved, electric power consumption can be decreased, and the thin film transistors are finely formed. The circuit board of the present invention includes both of the bottom gate thin film transistor and the top gate thin film transistor. Without increase in production steps, the double gate thin film transistor is formed, and performances of the circuit can be enhanced. Also if the double gate thin film transistor is formed, the top gate thin film transistor and/or the bottom gate thin film transistor, may be formed in addition to the double gate thin film transistor. The type of the other thin film transistors is not especially limited.

The present invention is also a display device including the above-mentioned circuit board. Examples of the above-mentioned display device include a liquid crystal display device and an organic electroluminescent display device. The display device including the above-mentioned circuit board includes the monolithic circuit in which high-performance thin film transistors with enhanced reliability are arranged, and so the device can exhibit excellent display characteristics.

### EFFECT OF THE INVENTION

According to the circuit board of the present invention, a film that is used as a gate insulating film and a film that suppresses impurities from diffusing from a substrate can be individually formed. So TFTs including a gate insulating film that can suppress impurity diffusion from the substrate and the like and that has a high insulating property can be formed.

### BEST MODES FOR CARRYING OUT THE INVENTION

The present invention is mentioned in more detail below with reference to Embodiments using drawings, but not limited thereto.

### Embodiment 1

FIG. 1 is a cross-sectional view schematically showing a configuration of a circuit board in accordance with Embodiment 1. In Embodiment 1, a bottom gate TFT, a top gate TFT, and a storage capacitor element for a pixel, each constituting a driving circuit, are formed.

According to the circuit board in Embodiment 1 shown in FIG. 1, a base coat film 11 made of silicon nitride is formed to have a thickness of 50 nm over the entire substrate 10, and thereon, a first gate electrode 19b of the bottom-gate TFT and a storage capacitor lower electrode 19c for a pixel are formed to each have a thickness of 300 nm. A first insulating film 12a with a thickness of 100 nm is arranged over the entire substrate to cover the first gate electrode 19b and the storage capacitor lower electrode 19c. The first insulating film 12a is made of silicon oxide, prepared using TEOS as raw material gas, and functions as a gate insulating film of the bottom gate TET.

A semiconductor layer that is made of polycrystalline silicon and has a thickness of 45 nm is formed on the first insulating film 12a as a semiconductor layer 13a of the top gate TET, a semiconductor layer 13b of the bottom gate TFT, and a storage capacitor upper electrode 13c. A low concentration dopant region 21 is formed between a channel region of the semiconductor layer 13b and each of source and drain regions of the semiconductor layer 13b, and these regions constitute an LDD structure. On the semiconductor layer, a second insulating film 14 with a thickness of 50 nm is formed. A second gate electrode 19a with a thickness of 300 nm is formed on the second insulating film 14 in a region where the semiconductor layer 13a of the top gate TFT is arranged. As layers upper than these members, a cap layer (insulating film) 15 with a thickness of 50 nm, a first interlayer film (a first interlayer insulating film) 16 with a thickness of 250 nm, and a second interlayer film (a second interlayer insulating film) 17 with a thickness of 700 nm are stacked in this order. Source and drain electrodes 18 that are connected to the semiconductor layer 13a of the top gate TET and the semiconductor layer 13b of the bottom gate TFT, respectively, through contact holes that penetrate the second insulating film 14, the cap layer 15, the first interlayer film 16, and the second interlayer film 17.

According to the above-mentioned configuration, the bottom gate TFT can be preferably used as a high-voltage TFT, and the top gate TFT can be preferably used as a low-voltage TFT. Accordingly, a high-performance circuit can be formed. In addition, the storage capacitor for the pixel in which generation of ESE) breakdown is effectively suppressed can be formed. TFTs for pixel switching can be formed in the same production step where the bottom gate TFT and/or the top gate TFT (particularly preferably, the bottom gate TET) are arranged.

The production method of the circuit board in accordance with Embodiment 1 is mentioned below.

The substrate 10 is rinsed and pre-annealed as pre-treatments. The substrate 10 is not especially limited, and a glass substrate, a resin substrate, and the like, are preferable in view of costs. The following steps (1) to (15) are performed then.

### (1) Step of Forming Base Coat Film

The base coat film 11 is formed on the substrate 10 by PECVD (plasma enhanced chemical vapor deposition), and the like. In Embodiment 1, a mixed gas of monosilane (SiH₄) and ammonia (NH₃), and the like, is used as raw material gas for forming a silicon nitride (SiNx) film as the base coat film 11. A SiON film, a SiO₂ film, and the like, may be used as the base coat film 11. If a SiON film is used as the base coat film 11, diffusion of ion impurities can be prevented, and further such a SiON film has excellent compatibility with the first insulating film 12a that is formed thereabove to improve the quality of the film 12a. If the SiO₂ film is used as the base coat film 11, the SiO₂ film has excellent compatibility with the first insulating film 12a that is formed thereabove to improve the quality of the film 12a. The material for the base coat film 11 is not especially limited to the above-mentioned SiNₓ film, SiON film, and SiO₂ film. Instead of such films, other materials may be used. Materials that can provide excellent flatness, materials with high thermal conductivity, and the like, are preferable.

### (2) Step of Forming First Gate Electrode

A tantalum nitride (TaN) film and a tungsten (W) film are formed in this order by sputtering and the like. Then a resist film is formed by spin coating and the like, and then patterned into a desired shape by photolithography. Then the W/TaN multi-layer film is etched to form the first gate electrode 19b.

### (3) Step of Forming First Insulating Film

The first insulating film 12a is formed by PECVD, and the like. According to Embodiment 1, a silicon oxide film formed using TEOS as raw material gas is used. Due to use of silicon oxide, a gate insulating film with high insulating property can be formed in the bottom gate ITT. The material for the first insulating film 12a is not limited to the silicon oxide film formed using TEOS as raw material gas, and insulating materials can be used.

### (4) Step of Forming Semiconductor Layer

An amorphous silicon (a-Si) film is formed by PECVD, and the like. SiH₄, disilane (Si₂H₆), and the like, may be used as raw material gas for the a-Si film.

Hydrogen exists in the a-Si film formed by PECVD, and so the a-Si film is subjected to a treatment for reducing the concentration of the hydrogen (dehydration treatment) at about 500° C. Instead of the dehydration treatment, a metal catalyst may be applied on the a-Si film as a pretreatment for forming a CG (continuous grain) -silicon film. Successively, the a-Si film is melt by laser annealing, and then cooled and solidified to give a p-Si film. According to the present Embodiment, excimer laser annealing is adopted. The base coat film 11 is arranged over the entire substrate 10, and so heat by laser irradiation is uniformly diffused on the substrate 10, and the crystallinity of the polycrystalline silicon (p-Si film) can be improved. A heat treatment for solid phase crystallization may be performed as a pretreatment before the laser annealing. Then, the p-Si film is patterned by dry etching using carbon tetrafluoride (CF₄) gas to give the semiconductor layers 13a and 13b and the storage capacitor upper electrode 13c.

### (5) Step of Forming Second Insulating Film

The second insulating film 14 made of silicon oxide is formed by PECVD using TEOS gas as raw material gas. A SiON film and the like may be used as the second insulating film 14. The material for the film 14 is not especially limited as long as it is an insulating material.

### (6) Ion Doping Step

In order to offset the difference in threshold voltage between the Nch-TFT and the Pch-TFT, the entire semiconductor layers 13a and 13b are doped with ions. The threshold voltage of the silicon film formed on the substrate 10 is shifted to minus direction from a proper value. By doping the entire semiconductor layers 13a and 13b with trivalent atoms such as boron, the threshold voltage of the Pch-TFT can be optimized. There is no need to perform this doping if the threshold voltage of the Pch-TFT does not need to be controlled.

### (7) Impurity Implantation Step (Nch-TFT Region)

In order to control a threshold voltage of the Nch-TFT, a resist film is formed to cover a region where the Pch-TFT is formed using photolithography and the like, and a gate region (channel region) of the Nch-TFT of the semiconductor layers 13a and/or 13b is doped with trivalent atoms such as boron by ion doping. This doping into the gate region is performed to adjust the threshold voltages between the Nch-TFT and Pch-TFT. As a result of this doping, the threshold voltage of the Nch-TFT is matched to that of the Pch-TFT. In addition, as a result of this doping into the gate region, the electrical conductivity of the gate region can be enhanced.

### (8) Step of Forming Second Gate Electrode

A tantalum nitride (TaN) film and a tungsten (W) film are formed in this order by sputtering and the like. Then a resist film is formed, and then patterned into a desired shape by photolithography. Then, the TaN/W multi-layer film is etched to form the second gate electrode 19a.

### (9) Step of Forming LDD Structure

First, the second gate insulating film 14 is formed, and thereon, a resist is applied. Then, the resist is exposed to light from the back surface side of the substrate using the first gate electrode 19b as a mask for self-aligned doping. According to the self-alignment technique, ions can be implanted without misalignment of the mask, and further the mask used for exposure can be decreased by one. Successively, the resist that has been exposed is removed, and low-concentration ions are implanted into a region between the channel region of the bottom gate TFT and each of the drain region and the source region, from the front side of the substrate 10. In the below-mentioned step (11) of forming the source and drain regions, a resist is newly applied on the second insulating film 14 and patterned, and then, the source and drain regions are formed by front exposure using a mask. The LDD structure is formed, and thereby, an electric field strength inside the channel can be eased, and reliability of the transistor can be improved. If the TFT used as a pixel switching is formed simultaneously with the bottom gate TFT, an LDD structure can be formed in the pixel-switching TFT.

### (10) Step of Forming Source and Drain Regions

Then, a resist film is patterned into a desired shape by photolithography, and, then, a region that is to constitute the source and drain regions of the Nch-TFT is doped with a high concentration of pentavelent atom such as phosphorus and a region that is to constitute the source and drain regions of the Pch-TFT is doped with a high concentration of trivalent atom such as boron by ion doping. The semiconductor layers 13a and 13b are subjected to a thermal activation treatment for 5 minutes at about 700° C. to activate the impurity ions existing therein. As a result, the electrical conductivity of the source and drain regions can be enhanced. For the activation, radiation of excimer laser may be employed, for example. Simultaneously, the semiconductor layer that is to constitute the storage capacitor upper electrode 13c is doped with high-concentration impurities, and subjected to a thermal activation treatment.

### (11) Step of Forming Cap Layer

Then, the cap layer 15 formed from a SiO₂ film is formed over the entire substrate 10 by PECVD using TEOS as raw material gas. A SiNₓ film, a SiON film, and the like, can be used as a material for the cap layer 15.

### (12) Step of Forming Interlayer Film

Then, the first interlayer film 16 formed from a silicon nitride (SiNₓ) film is formed by PECVD over the entire substrate 10 using a mixed gas of monosilane (SiN₄) and ammonia (NH₃) and the like as raw material gas. By PECVD using TEOS as raw material gas, the second interlayer film 17 formed from a SiO₂ film is formed over the entire substrate 10. A SiNₓ film, a SiON film, and the like can be used as a material for the first interlayer film 16 and the second interlayer film 17.

### (13) Step of Forming Contact Hole

Then, a resist film is formed on the second interlayer film 17 by spin coating and the like. The resist film patterned into a desired shape by photolithography, and then, the second insulating film 14, the cap layer 15, the first interlayer film 16, and the second interlayer film 17 are wet-etched with a hydrofluoric acid etching solution, thereby forming a contact hole for connecting the source and drain electrodes 18 to the source and drain regions of the semiconductor layer 13a of the top gate TFT and the semiconductor layer 13b of the bottom gate TFT. Instead of the wet-etching, dry-etching or a combination of dry-etching and wet-etching may be used.

### (14) Hydrogen Termination Step

Hydrogen termination of an interface between the channel portion of the semiconductor layer 13a and the second insulating film 14, and an interface between the channel portion of the semiconductor layer 13b and the first insulating film 12a is performed by heat treatment for 1 hour at about 400° C. Hydrogen existing in the silicon nitride film that constitutes the first interlayer film 16 is used for the termination.

### (15) Step of Forming Source and Drain Electrodes

A titanium (Ti) film, an aluminum (Al) film, and a Ti film are formed in this order by sputtering, and the like. A resist film is formed into a desired shape by photolithography, and then, the metal multi-layer film of Ti/Al/Ti is patterned by dry etching, thereby forming source and drain electrodes 18. The source electrode 18 is conducted to the source region and the drain electrode 18 is conducted to the drain region, each through a contact hole formed in the second insulating film 14, the cap layer 15, the first interlayer film 16, and the second interlayer film 17.

Through the above-mentioned steps, TFTs constituting the driving circuit and the storage capacitor for pixels can be formed. TFTs used for pixel switching may be simultaneously formed by these steps.

According to the circuit board of the present Embodiment, two insulating films, i.e., the base coat film 11 and the first insulating film 12a, are formed below the top gate TFT, and the base coat film 11 is used as a base coat film for bottom gate TFT, and further, the first insulating film 12a is used as a gate insulating film of the bottom gate TFT. Thus, the two insulating films are formed below the top gate TFT, and so as the base coat film 11, an insulating film through which impurities hardly permeate, such as a SiN film, can be used The thickness of the base coat film 11 is varied, and thereby the thickness of the two insulating films arranged below the top gate TFT can be prevented from being influenced by the thickness of the gate insulating film (the first insulating film 12a) of the bottom gate TFT. As a gate insulating film (the first insulating film 12a) of the bottom gate TFT, an upper one of the two insulating films is used. As a gate insulating film of the bottom gate TFT, not the base coat film 11 such as a SiN film, which generally has not so excellent film qualities but the insulating film with excellent film qualities, such as the silicon oxide film prepared using TEOS as raw material gas, can be used.

### Embodiment 2

FIG. 2 is a cross-sectional view schematically showing a configuration of a circuit board in accordance with Embodiment 2. According to Embodiment 2, a bottom gate TFT, a top gate TFT, and a storage capacitor element for a pixel, each constituting a driving circuit, are arranged, and the top gate TFT is arranged also in a region overlapping with the bottom gate TFT.

According to the circuit board of Embodiment 2 shown in FIG. 2, in a region where the bottom gate TFTs are arranged, a double gate TFT composed of the bottom gate TFT and the top gate TFT stacked is arranged. The bottom gate TFT includes a base coat film 11, a first gate electrode 19d, a first insulating film 12d, and a semiconductor layer 13d, stacked in this order from the substrate 10 side. The top gate TFT includes a semiconductor layer 13d, a second insulating film 14d, and a third gate electrode 20, stacked in this order from the substrate 10 side. A cap layer 15d, a first interlayer film 16d, and a second interlayer film 17d are stacked on the third gate electrode 20 in this order from the substrate 10 side over the entire substrate 10. The source and drain electrodes led are connected to the semiconductor layer 13d. Although not shown in FIG. 2, the third gate electrode 20 is connected to the first gate electrode 19d through a contact hole that penetrates the first insulating film 12d and the second insulating film 14d. So the same signal can be fed into the gate electrode 19d and the third gate electrode 20. The low concentration dopant region 21d constituting an LDD structure is formed in the semiconductor layer 13d. In a region where the top gate thin film transistor is to be arranged, the base coat film 11, the first insulating film 12d, a semiconductor layer 13e, the second insulating film 14d, a second gate electrode 19e, the cap layer 15d, the first interlayer film 16d, and the second interlayer film 17d are stacked in this order from the substrate 10 side. The third gate electrode 20 is formed together with the second gate electrode 19 in the same step. In the region where the storage capacitor is to be formed, the base coat film 11, a storage capacitor lower electrode 19f, the first insulating film 12d, a storage capacitor upper electrode 13f, which is formed in the same step of forming the semiconductor layer 13d and 13e, the second insulating film 14d, the cap layer 15d, the first interlayer film 16d, and the second interlayer film 17d are stacked in this order from the substrate 10 side. The first gate electrode 19d and the storage capacitor lower electrode 19f each have a thickness of 200 nm. The first insulating film 12d has a thickness of 100 nm. The semiconductor layers 13d, 13e, and the storage capacitor upper electrode 13f each have a thickness of 50 nm. The second insulating film 14d has a thickness of 50 nm. The second gate electrode 19e and the third gate electrode 20 each have a thickness of 350 nm. The cap layer 15d has a thickness of 50 nm. The first interlayer film 16d has a thickness of 250 nm. The second interlayer film 17d has a thickness of 700 nm.

Double gate TFTs including a bottom gate TFT and a top gate TFT stacked one above the other are arranged in the circuit board, and thereby an electric current is carried between the source and the drain of the top gate TFT in the double gate TFT. Compared with use of only the bottom gate TFT, the electric current that is carried between the source and the drain can be increased.

### Comparative Embodiments 1 and 2

FIG. 3 is a cross-sectional view schematically showing a configuration of a circuit board in accordance with Comparative Embodiments 1 and 2. As shown in FIG. 3, the configuration of the circuit board in accordance with Comparative Embodiment 1 is the same as in Embodiment 1, except that a first insulating film 12b, which is a single layer, i.e. , a silicon nitride film with a thickness of 100 nm, is formed, and no base coat film 11 is arranged. The configuration of the circuit board in accordance with Comparative Embodiment 2 is the same as in Comparative Embodiment 1, except that the first insulating film 12b is formed from a silicon oxide film with a thickness of 100 nm. According to Comparative Embodiments 1 and 2, the base coat film 11 is not arranged below the first gate electrode 19b. Therefore, impurities that are diffused from the substrate 10 might contaminate the first gate electrode 19b. The base coat film is not arranged below the first gate electrode 19b, and the thermal diffusion through the first insulating film 12b and the like varies from position to position. For example, in a step of heating the semiconductor layer for polycrystallization, the crystallinity of polycrystalline silicon might be deteriorated.

In Comparative Embodiment 1, the silicon nitride film is used as the first insulating film 12b . So impurity contamination into the semiconductor layers 13a and 13b and the like from the substrate 10 can be suppressed. On the other hand, a silicon nitride film is generally inferior in insulating property to a silicon oxide film formed using TEOS. Further, an interface state between the silicon nitride film and the semiconductor layers 13a and 13b is inferior to that when a silicon oxide film is used as the film 12b. As a result, the transistor characteristics might be deteriorated.

In Comparative Embodiment 2, the silicon oxide film is used as the first insulating film 12b, and so the insulating property of the gate insulating film is improved compared with the silicon nitride film having the same thickness is formed. On the other hand, the silicon oxide film has a lower effect of suppressing the impurity diffusion than that of the silicon nitride film, and so impurities are diffused through the first insulating film 12b into the semiconductor layers 13a and 13b, the storage capacitor upper electrode 13c, and the like, which might result in deterioration of the characteristics of the semiconductor layers 13a and 13b, and the storage capacitor element.

The present application claims priority to Patent Application No. 2007-208372 filed in Japan on Aug. 9, 2007 under the Paris Convention and provisions of national law in a designated State, the entire contents of which are hereby incorporated by reference.

### BRIEF DESCRIPTION OF DRAWINGS

FIG. 1 is a cross-sectional view schematically showing a configuration of the circuit board in accordance with Embodiment 1.

FIG. 2 is a cross-sectional view schematically showing a configuration of the circuit board in accordance with Embodiment 2.

FIG. 3 is a cross-sectional view schematically showing a configuration of the circuit board in accordance with Comparative Embodiments 1 and 2.

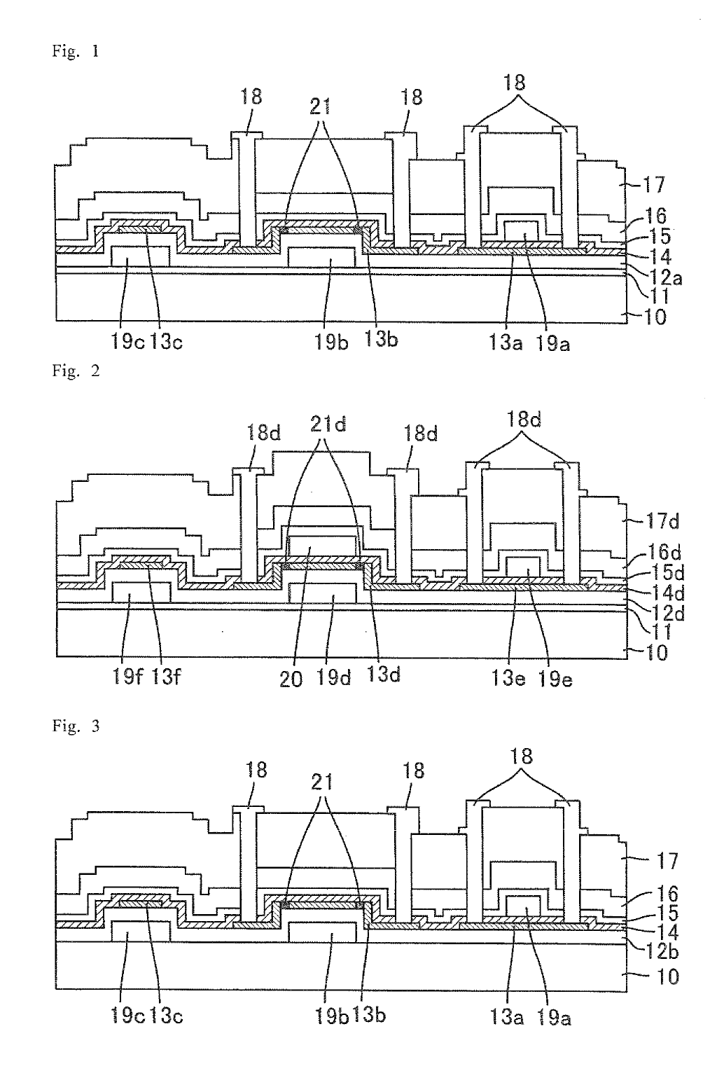

### EXPLANATION OF NUMERALS AND SYMBOLS

10: Substrate
11: Base coat film
12a, 12b, 12d: First insulating film
13a, 13b, 13d, 13e: Semiconductor layer
13c, 13f: Storage capacitor upper electrode
14, 14d: Second insulating layer
15, 15d: Cap layer
16, 16d: First interlayer film
17, 17d: Second interlayer film
18, 18d: Source and drain electrodes

19a, 19e: Second gate electrode

19b, 19d: First gate electrode

19c, 19f: Storage capacitor lower electrode

20: Third gate electrode

21, 21d: Low-concentration dopant region

1. A circuit board comprising a bottom gate thin film transistor and a first top gate thin film transistor on a substrate,
the bottom gate thin film transistor including a first gate electrode, a first gate insulating film, and a first semiconductor layer, stacked in this order from a side of the substrate,
the first top gate thin film transistor including a second semiconductor layer, a second gate insulating film, and a second gate electrode, stacked in this order from the side of the substrate,
wherein two or more insulating films are arranged between the substrate and the second semiconductor layer, and
at least a base coat film arranged between the substrate and the first gate electrode, and the first gate insulating film constitute the two or more insulating films.

2. The circuit board according to claim 1,
wherein the first gate insulating film and the second gate insulating film are different in thickness.

3. The circuit board according to claim 2,
wherein the first gate insulating film has a thickness larger than a thickness of the second gate insulating film.

4. The circuit board according to claim 1,
wherein the base coat film contains silicon nitride.

5. The circuit board according to claim 1,
wherein the first gate insulating film contains silicon oxide.

6. The circuit board according to claim 1,
wherein the circuit board further comprises a double gate thin film transistor,
the double gate thin film transistor is composed of the bottom gate thin film transistor and a second top gate thin film transistor formed in a region overlapping with the bottom gate thin film transistor.

7. A display device comprising the circuit board according to claim 1.
